(19) United States
(12) Patent Application Publication
(10) Pub. No.: US 2003/0170987 A1
(43) Pub. Date: Sep. 11, 2003

(54) Method for manufacturing slurry

(76) Inventor: Ki Hong Yang, Seoul (KR)

Correspondence Address: LADAS & PARRY, 224 SOUTH MICHIGAN AVENUE, SUITE 1200, CHICAGO, IL, 60604, US

(21) Appl. No.: 10/293,446

(22) Filed: Nov. 13, 2002

(30) Foreign Application Priority Data
Mar. 6, 2002 (KR) 2002-11822

(51) Int. Cl. H01L 21/302; H01L 21/461

(52) U.S. Cl. 438/689

(57) ABSTRACT

Disclosed is a method for manufacturing slurry capable of stably polishing polycrystal silicon without change of surface roughness in a Chemical Mechanical Polishing process. The disclosed includes hydroxide ion added to the slurry in order to decrease acidity and increase alkalinity.

### BACKGROUND OF THE INVENTION

1. Field of the Invention

The present invention relates to a method for manufacturing slurry and, more particularly, to a method for manufacturing slurry capable of stably polishing polycrystal silicon without change of surface roughness in a Chemical Mechanical Polishing process.

2. Description of the Prior Art

A Chemical Mechanical Polishing process has been developed to accomplish wide area planation and depth of focus in multi-layered semiconductor devices and the application of the process will be increased since semiconductor devices become smaller and wafers become larger. The Chemical Mechanical Polishing process comprises an insulating layer polishing step for wide area planation, a STI (Swallow Trench Isolation) step and a metal polishing step to use a multi-layered line.

In the Chemical Mechanical Polishing process, chemical reaction is generated by the reaction of chemicals in slurry and layer. And, mechanical reaction means that energy from polishing device is transmitted to particles of slurry and then, chemically-reacted layer is mechanically removed by the particles.

The slurry generally comprises ionized water, chemicals and particles and a small amount of surfactants can be added to improve Chemical Mechanical Polishing properties.

The particles of slurry for Chemical Mechanical Polishing process include many components such as Na, Mg, Al, Ti, Mn, Fe, Ni, Cu, Zn and Zr, wherein silica is generally used as slurry for polishing oxide and polycrystal silicon layer and Alumina Al2O3 is generally used as slurry for polishing metals such as W and Cu.

In the slurry for polishing polycrystal silicon and oxide, materials including acid components such as HNO₃, HF and CH₃COOH are employed to decompose the polycrystal silicon. Here, the HNO₃ is employed to generate SiO₂, HF is employed to etch SiO₂ and CH₃COOH is employed as a buffering agent to delay generation of SiO₂ by HNO₃. When the amount of HNO₃ is decreased and that of HF is increased, generation of SiO₂ is delayed and etch rate is lowered, and when the amount of HNO₃ is increased and that of HF is decreased, decomposition of SiO₂ is delayed and etch rate is lowered.

As a result, when acid components are increased, polycrystal silicon is efficiently decomposed.

FIG. 1A is a top plan view of polycrystal silicon whereon CMP process is performed by using conventional slurry.

FIG. 1B is an enlarged view of FIG. 1A, wherein a reference code 10 shows a region having no change of surface roughness by slurry in a polycrystal silicon polishing process and a reference code 12 shows a region having change of surface roughness by slurry.

As shown in FIGS. 1A and 1B, the surface roughness of polycrystal silicon is changed by slurry in polycrystal silicon polishing process, thereby increasing resistance and defects due to surface attack in contact. As a result, the conventional method has a problem that it is not easily distinguished from scratch of CMP and the process is delayed.

### SUMMARY OF THE INVENTION

Therefore, the present invention has been proposed to solve the above-mentioned problems and a primary objective of the present invention is to provide a method for manufacturing slurry capable of reducing surface attack of polycrystal silicon to a minimum.

In order to accomplish the above objective, the present invention provides a method for manufacturing slurry wherein acidity is decreased and alkalinity is increased by adding hydroxide ion to acid slurry for polishing polycrystal silicon.

### BRIEF DESCRIPTION OF THE DRAWINGS

The above objects, and other features and advantages of the present invention will become more apparent after reading the following detailed description when taken in conjunction with the drawings.

FIG. 1A is a top plan view of polycrystal silicon wherein CMP process is performed by using conventional slurry.

FIG. 1B is an enlarged view of FIG. 1A.

FIG. 2 is a graph showing a removal rate of oxide layer by the change of acidity.

FIG. 3 is a top plan view of polycrystal silicon according to the present invention.

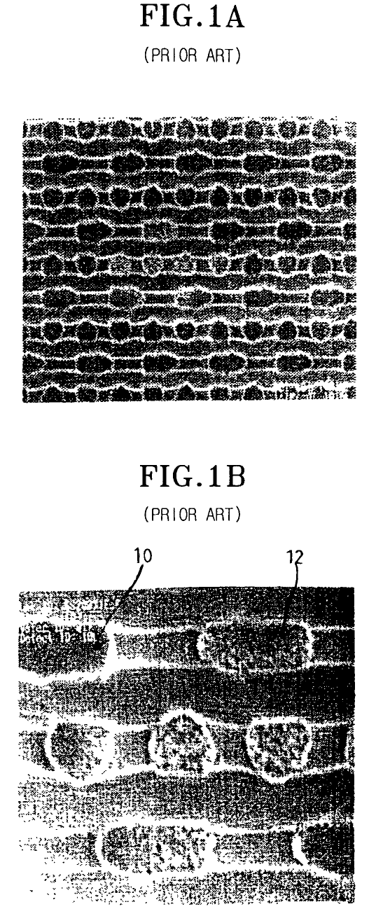

### DETAILED DESCRIPTION OF THE INVENTION

According to the present invention, slurry for polishing polycrystal silicon and oxide is manufactured by adding OH− to acid slurry for polishing polycrystal silicon and oxide including HNO₃, HF and CH₃COOH to decrease acidity and increase alkalinity.

The slurry of the present invention comprises ionized water, chemicals and particles and a small amount of surfactants can be added to improve chemical mechanical polishing properties. The particles include many components such as Na, Mg, Al, Ti, Mn, Fe, Ni, Cu, Zn and Zr and silica is generally used to polish oxide and polycrystal silicon layer.

The OH− solution includes strongly alkaline such as KOH, Ca(OH)₂, NaOH, and Ba(OH)₃ and weak alkaline such as NH₄OH, Cu(OH)₂, and Al(OH)₃, more desirably NaOH, NH₄OH and KOH can be used. According to reaction (I), NaOH is ionized to be separated into Na+ and OH− and according to reaction (II), NH₄OH is separated into NH₄+ and OH−. According to reaction (III), KOH is separated into K+ and OH−. The separated OH− reacts with acid slurry for polishing polycrystal silicon and oxide, thereby decreasing acidity and increasing alkalinity.

NaOH→Na+++OH− (I)

NH₄OH→NH₄++OH− (II)

KOH→K++OH− (III)

When the polycrystal silicon is subjected to Chemical Mechanical Polish process by using slurry including alkaline components such as NaOH, NH₄OH and KOH, the slurry has a viscosity of below 3.0 cps, a specific gravity of 1.0˜1.5, a particle size of 110˜180 nm and solid content of over 11% to reduce polycrystal silicon attack to a minimum.

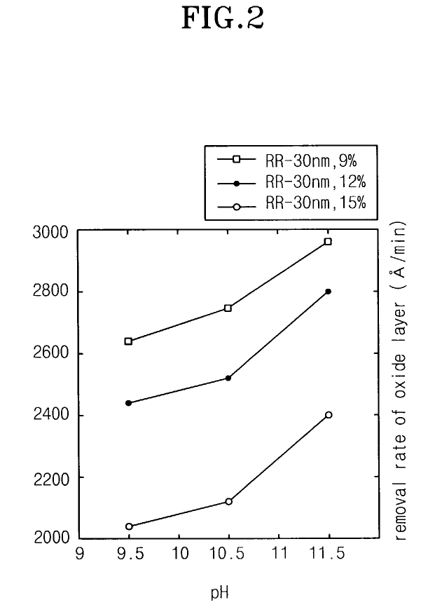

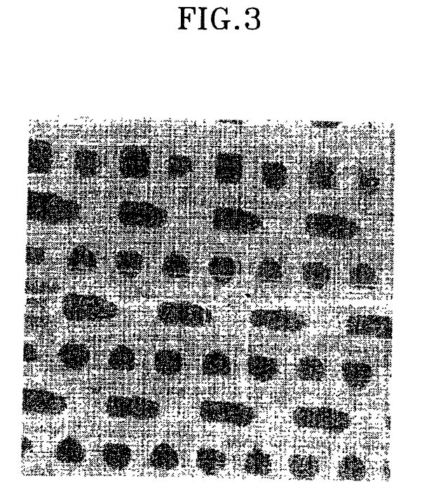

FIG. 2 is a graph showing a removal rate of oxide layer by the change of acidity and FIG. 3 is a top plan view of polycrystal silicon according to the present invention.

According to the present invention, hydroxide ion is added to slurry for polishing polycrystal silicon including acid components such as HNO₃, HF and CH₃COOH. As shown in FIG. 2, when the acidity (pH) is increased, the removal rate of oxide layer is also increased. It is desirable to maintain the acidity over 11 in order to efficiently perform the removal of oxide layer.

Referring to FIG. 3, it is possible to prevent the change of surface roughness since the surface of polycrystal silicon is not attacked by slurry.

As described above, according to the present invention, OH− is added to slurry for polishing polycrystal silicon, thereby decreasing acidity and increasing alkalinity. Therefore, it is possible to increase a removal rate of oxide and decrease a removal rate of polycrystal silicon, thereby reducing polycrystal silicon attack by slurry after CMP process.

As a result, the present invention has an advantage that the yield of polishing process is increased and the surface of polycrystal silicon has no change of surface roughness.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing slurry for polishing polycrystal silicon and oxide including acid components such as HNO₃, HF and CH₃COOH, wherein hydroxide ion is added to the slurry in order to decrease acidity and increase alkalinity.

2. The method of claim 1, wherein the acidity is maintained over Ph 11.

3. The method of claim 1, wherein the hydroxide ion solution is one selected from NaOH, NH₄OH and KOH.

4. The method of claim 1, wherein the slurry for polishing polycrystal silicon has a viscosity of below 3.0 cps.

5. The method of claim 1, wherein the slurry for polishing polycrystal silicon has a specific gravity of 1.0˜1.5.

6. The method of claim 1, wherein the slurry for polishing polycrystal silicon has a solid content over 11%.

7. The method of claim 1, wherein the slurry for polishing polycrystal silicon has a particle size of 110˜180 nm.
